(19) United States
(12) Patent Application Publication
(10) Pub. No.: US 2020/0243712 A1
(43) Pub. Date: Jul. 30, 2020

(54) INSPECTION METHOD FOR LED CHIP, INSPECTION DEVICE THEREFOR, AND MANUFACTURING METHOD FOR LED DISPLAY

(71) Applicant: V TECHNOLOGY CO., LTD., Yokohama-shi (JP)

(72) Inventors: Koichiro FUKAYA, Yokohama-shi (JP); Koichi KAJIYAMA, Yokohama-shi (JP)

(21) Appl. No.: 16/847,531

(22) Filed: Apr. 13, 2020

Related U.S. Application Data
(63) Continuation of application No. PCT/JP2018/038628, filed on Oct. 17, 2018.

(30) Foreign Application Priority Data
Oct. 26, 2017 (JP) 2017-207183

(51) Int. Cl. H01L 33/00; H01L 25/075; H01L 33/62

(52) U.S. Cl. CPC H01L 33/0095; H01L 25/0753; H01L 2933/0066; H01L 33/62; H01L 33/0093

(57) ABSTRACT

An inspection method for multiple LED chips 6 formed on a sapphire substrate 7, comprising: a first step of positioning the sapphire substrate 7 above an inspection wiring board 11 such that each electrode 10 of the multiple LED chips 6 is arranged above a corresponding electrode pad 12 provided on the inspection wiring board 11 at a position corresponding to the electrode 10, and then placing the sapphire substrate 7 on the inspection wiring board 11; a second step of electrically connecting each electrode 10 of the multiple LED chips 6 and the corresponding electrode pad 12 of the inspection wiring board 11; and a third step of supplying a current to the multiple LED chips 6 through the inspection wiring board 11, and determining the quality of the LED chips 6.

This application is a continuation application of PCT/JP2018/038628, filed on Oct. 17, 2018.

### BACKGROUND OF THE INVENTION

### Field of the Invention

The present invention relates to inspection methods for light emitting diode (LED) chips, and more particularly, relates to inspection methods for LED chips capable of determining the quality of LED chips without detaching the LED chips from wafers, and also relates to inspection devices therefor, and to manufacturing methods for LED displays.

### Description of Related Art

A conventional manufacturing method for an LED display includes the steps of: transferring multiple LED chips, formed on a sapphire substrate, temporarily, to a transfer board; from among the multiple LED chips transferred to the transfer board, selectively removing LED chips at electrode pitch of a wiring board, by vacuum-chucking by a chucking head; and mounting the LED chips, removed by the chucking head, on the wiring board (for example, JP 2008-77100 A).

Furthermore, J P 2008-77100 A1 discloses that LED chips are subjected to inspection while being held on the transfer board.

In such a conventional manufacturing method for an LED display, the multiple LED chips are temporarily transferred from the sapphire substrate to the transfer board, and are subjected to inspection. Then, non-defective LED chips are removed by vacuum-chucking with the chucking head, and are mounted on the wiring board. Thus, there has been a problem in that the manufacturing process is complicated.

Furthermore, in the conventional manufacturing method for an LED display, since the LED chips are subjected to inspection before being mounted on the wiring board, defective elements can be removed early to improve yield. However, since the inspection is performed after temporarily transferring the LED chips from the sapphire substrate to the transfer board, there remains the problem of complicated manufacturing process.

### SUMMARY OF THE INVENTION

In view of the problem, an object of the present invention is to provide an inspection method for LED chips capable of determining the quality of an LED chip without detaching the LED chip from a wafer, and to provide an inspection device therefor, and a manufacturing method for an LED display.

In order to achieve the object, according to the present invention, there is provided an inspection method for multiple LED chips formed on a wafer, comprising: a first step of positioning the wafer above a wiring board such that each electrode of the multiple LED chips formed on the wafer is arranged above a corresponding electrode pad provided on the wiring board, and then placing the wafer on the wiring board; a second step of electrically connecting each electrode of the multiple LED chips and the corresponding electrode pad of the wiring board; and a third step of supplying a current to the multiple LED chips through the wiring board, and determining the quality of the LED chips.

Furthermore, according to the present invention, there is provided an inspection device for an LED chip for use in the inspection method for LED chips, comprising:

a wafer holding unit that holds a wafer on which multiple LED chips are formed;

a wiring board holding unit arranged to face the wafer holding unit, in which the wiring board holding unit holds a wiring board provided with multiple electrode pads at positions corresponding to positions of electrodes of the multiple LED chips;

an alignment unit that positions the wafer with respect to the wiring board such that each electrode of the multiple LED chips formed on the wafer is arranged above a corresponding electrode pad provided on the wiring board;

pressing unit that presses at least one of the wafer and the wiring board, to electrically connect each electrode of the multiple LED chips and the corresponding electrode pad of the wiring board; and a determination device that supplies a current to the multiple LED chips through the wiring board, and determines the quality of the LED chips.

Furthermore, according to the present invention, provided is a manufacturing method for an LED display, for use in mounting multiple micro LED chips formed on a transparent wafer on a wiring board after subjecting the multiple micro LED chips to the inspection method described above, comprising:

a first step of positioning the wafer above an inspection wiring board such that each electrode of the multiple micro LED chips formed on the wafer is arranged above a corresponding first electrode pad provided on the inspection wiring board, and then placing the wafer on the inspection wiring board;

a second step of pressing the wafer to electrically connect each electrode of the multiple micro LED chips and the corresponding first electrode pad of the inspection wiring board;

a third step of supplying a current to the multiple micro LED chips through the inspection wiring board, and determining the quality of the micro LED chips;

a fourth step of positioning the wafer above a display wiring board such that each electrode of the multiple micro LED chips formed on the wafer is arranged above a corresponding second electrode pad provided on the display wiring board, and then placing the wafer on the display wiring board; and a fifth step of irradiating micro LED chips determined to be non-defective with a laser light through the wafer, to selectively lift off, from the wafer, the irradiated micro LED chips, and to mount the lifted-off micro LED chips on the display wiring board.

According to the present invention, it is possible to determine the quality of LED chips without detaching the LED chips from a wafer. Therefore, it is possible to simplify the manufacturing process of an LED display and to reduce cost for manufacturing an LED display.

### BRIEF DESCRIPTION OF THE DRAWINGS

FIG. 1 is a schematic view illustrating an inspection device for an LED chip according to an embodiment of the present invention.

FIGS. 2A and 2B are views showing a wafer on which multiple micro LED chips are formed. FIG. 2A is a plan view, and FIG. 2B is an enlarged cross-sectional view of the main part.

FIGS. 3A and 3B are cross-sectional views for explaining elastic protrusions formed on first electrode pads of a wiring board for inspection for use in the inspection device. FIG. 3A illustrates an example, and FIG. 3B illustrates another example.

FIGS. 4A to 4C are explanatory views illustrating an inspection method for LED chips, according to the present invention.

FIG. 5 is a plan view schematically illustrating an LED display according to a first embodiment, manufactured using the inspection method for LED chips.

FIG. 6 is an enlarged cross-sectional view of the main part of FIG. 5.

FIG. 7 is an enlarged cross-sectional view of the main part illustrating an example of the configuration of an LED array substrate of the LED display.

FIGS. 8A to 8F are views illustrating a process in a first example of manufacturing the LED array substrate.

FIG. 9 is an enlarged cross-sectional view of the main part illustrating an example of the configuration of a wiring board in the LED array substrate.

FIGS. 10A to 10F are views illustrating a process in a second example of manufacturing the LED array substrate.

FIGS. 11A and 11B are views for explaining a manufacturing process of a fluorescent layer array of the LED display.

FIGS. 12A and 12B are explanatory views illustrating an assembling process of the LED array substrate and the fluorescent layer array.

FIG. 13 is an enlarged cross-sectional view of the main part of an LED display according to a second embodiment.

FIG. 14 is an enlarged cross-sectional view of the main part of an LED display according to a third embodiment.

FIG. 15 is a plan view schematically illustrating an LED display according to a fourth embodiment.

FIGS. 16A to 16B are plan views showing a display wiring board and sapphire substrates for red, green, and blue colors, for use in the fourth embodiment. FIG. 16A illustrates the display wiring board, and FIG. 16B illustrates sapphire substrates for red, green, and blue colors.

FIGS. 17A to 17C are explanatory views illustrating a first liftoff in the manufacture of the fourth embodiment. FIG. 17A shows the arrangement state of sapphire substrates for red, green, and blue colors, on the display wiring board. FIG. 17B shows the LED chip rows on the display wiring board after the liftoff. FIG. 17C shows the sapphire substrates for red, green, and blue colors after the liftoff.

FIGS. 18A to 18C are explanatory views illustrating a second liftoff in the manufacture of the fourth embodiment. FIG. 18A shows the arrangement state of sapphire substrates for red, green, and blue colors, on the display wiring board. FIG. 18B shows the LED chip rows on the display wiring board after the liftoff. FIG. 18C shows the sapphire substrates for red, green, and blue colors after the liftoff.

FIGS. 19A and 19B are explanatory views illustrating a third liftoff in the manufacture of the fourth embodiment. FIG. 19A shows the arrangement state of sapphire substrates for red, green, and blue colors, on the display wiring board. FIG. 19B shows the LED chip rows on the display wiring board after the liftoff.

### DESCRIPTION OF PREFERRED EMBODIMENTS

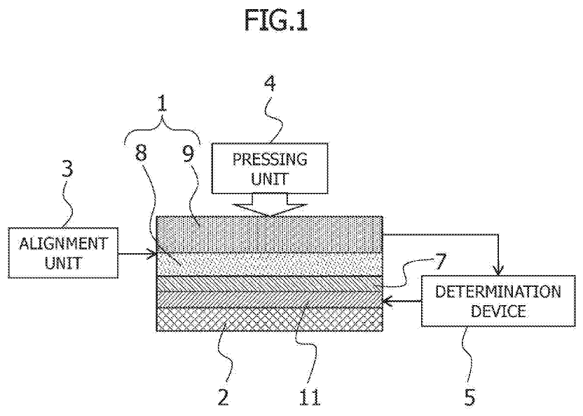

Hereinbelow, embodiments of the present invention will be described in detail with reference to the accompanying drawings. FIG. 1 is a schematic view illustrating an inspection device for an LED chip according to an embodiment of the present invention. This LED chip inspection device enables inspection without detaching multiple LED chips from a wafer, and it is provided with a wafer holding unit 1, a wiring board holding unit 2, an alignment unit 3, a pressing unit 4, and a determination device 5.

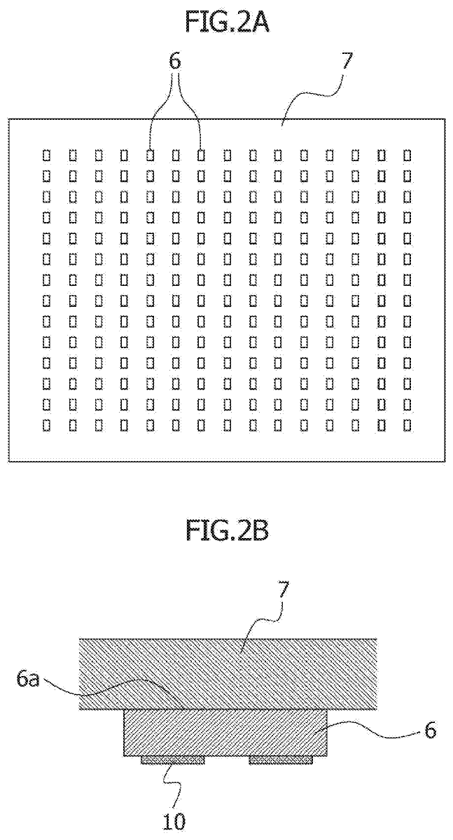

As shown in FIG. 2A, the wafer holding unit 1 is configured to hold a wafer on which multiple micro LED chips 6 are formed in a matrix pattern at a constant arrangement pitch (for example, at the same arrangement pitch as the pixel pitch of an LED display). The wafer holding unit 1 is provided with: a transparent member 8 having an intake hole formed therethrough so as to vacuum-chuck a peripheral portion of the back of a sapphire substrate 7, serving as a wafer, opposite a surface on which the micro LED chips 6 are formed; and an image sensor 9, such as a CCD or a CMOS, arranged on the back of the transparent member 8 opposite the sapphire substrate 7, the image sensor 9 being used to obtain an image of an area of the sapphire substrate 7 in which the micro LED chips 6 are formed. The sapphire substrate 7 has a reference surface (for example, a notched surface), serving as a reference for arranging the substrate at a predetermined position, so that the sapphire substrate 7 can be always arranged to extend in the same direction during inspection and display manufacturing process. The wafer is not limited to the sapphire substrate 7, and may be any transparent substrate that transmits visible light, such as silicon carbide (SiC) or gallium nitride (GaN).

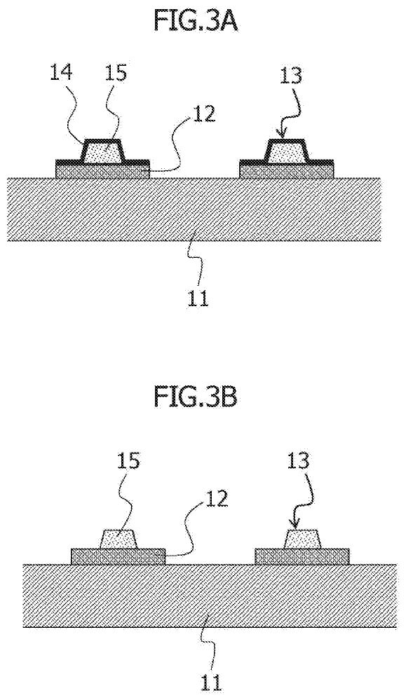

A wiring board holding unit 2 is arranged to face the wafer holding unit 1. The wiring board holding unit 2 is configured to hold a wiring board for inspection (“inspection wiring board”) 11 that is provided with multiple first electrode pads 12 (see FIGS. 3A and 3B), each arranged at a position corresponding to the position of a corresponding electrode 10 (see FIG. 2B) disposed opposite a light outcoupling surface 6a of the multiple micro LED chips 6 formed on the sapphire substrate 7. The wiring board holding unit 2 is provided with multiple intake holes so as to vacuum-chuck the back of the inspection wiring board 11 opposite the surface on which the first electrode pads 12 are formed.

The alignment unit 3 is provided to enable the wafer holding unit 1 to move and rotate in a two-dimensional direction parallel (horizontally) to the upper surface of the wiring board holding unit 2. The alignment unit 3 is configured to position the sapphire substrate 7 with respect to the inspection wiring board 11 such that each electrode 10 of the multiple micro LED chips 6 formed on the sapphire substrate 7 is arranged above a corresponding first electrode pad 12 provided on the inspection wiring board 11, while monitoring alignment marks formed on the sapphire substrate 7 and alignment marks formed on the inspection wiring board 11 by an imaging camera (not shown). The alignment unit 3 is configured to process the images obtained by the imaging camera to automatically perform alignment such that both alignment marks are aligned at predetermined positional relationships. Alternatively, the alignment may be manually performed.

The pressing unit 4 is provided to enable the wafer holding unit 1 to move in the vertical direction. The pressing unit 4 presses down the wafer holding unit 1 in the vertical direction to electrically connect each electrode 10 of the multiple micro LED chips 6 and the corresponding first electrode pads 12 of the inspection wiring board 11. The pressing unit 4 is provided with a pressure sensor (not shown), and is configured to apply a predetermined pressing force between the electrodes 10 of the micro LED chips 6 and the first electrode pads 12 of the inspection wiring board 11. Although the pressing unit 4 may be provided to enable the wiring board holding unit 2 to move, a case in which the pressing unit 4 is provided to press the wafer holding unit 1 will be explained in the following description.

In this case, as shown in FIGS. 3A and 3B, a first conductive elastic protrusion 13 is formed on each first electrode pad 12 of the inspection wiring board 11 by patterning. Thus, the electrical connection between each electrode 10 of the micro LED chips 6 and the corresponding first electrode pad 12 of the inspection wiring board 11 is made by the elastic deformation of the first elastic protrusion 13. Therefore, it is possible to achieve uniform contact between the electrodes 10 of the multiple micro LED chips 6 formed on the sapphire substrate 7 and the multiple first electrode pads 12 of the inspection wiring board 11. It is thereby possible to prevent a micro LED chip 6 from being erroneously determined to be defective due to contact failure.

Specifically, the first elastic protrusion 13 may be a resin columnar protrusion 15 having a surface on which a conductive film 14 of superior conductivity, such as gold or aluminum, is deposited, as shown in FIG. 3A, or may be a columnar protrusion 15 made of a conductive photoresist obtained by adding conductive fine particles, such as silver, to a photoresist, or be made of a conductive photoresist containing a conductive polymer, as shown in FIG. 3B.

The determination device 5 is provided to electrically connect to the inspection wiring board 11 and the image sensor 9. The determination device 5 is configured to supply a current to the multiple micro LED chips 6 through the inspection wiring board 11, and to determine the quality of the micro LED chips 6. The determination device 5 detects whether each micro LED chip 6 turns on or not, and senses the brightness and the wavelength of emitted light, by means of the image sensor 9 during supplying the current to the micro LED chips 6, to determine the quality of the micro LED chips 6, and stores the position coordinates or address of defective micro LED chips 6.

Next, an inspection method for LED chips using the inspection device configured as above will be described.

First, the sapphire substrate 7 provided with the multiple micro LED chips 6 is held by the wafer holding unit 1 with the back of the sapphire substrate 7 being vacuum-chucked. In this case, the sapphire substrate 7 is arranged to extend in a predetermined direction referring to the reference surface having, for example, a notch at an edge.

Next, the inspection wiring board 11 provided with the multiple first electrode pads 12 at positions corresponding to those of the electrodes 10 of the multiple micro LED chips 6 is held by the wiring board holding unit 2 with the back of the inspection wiring board 11 being vacuum-chucked.

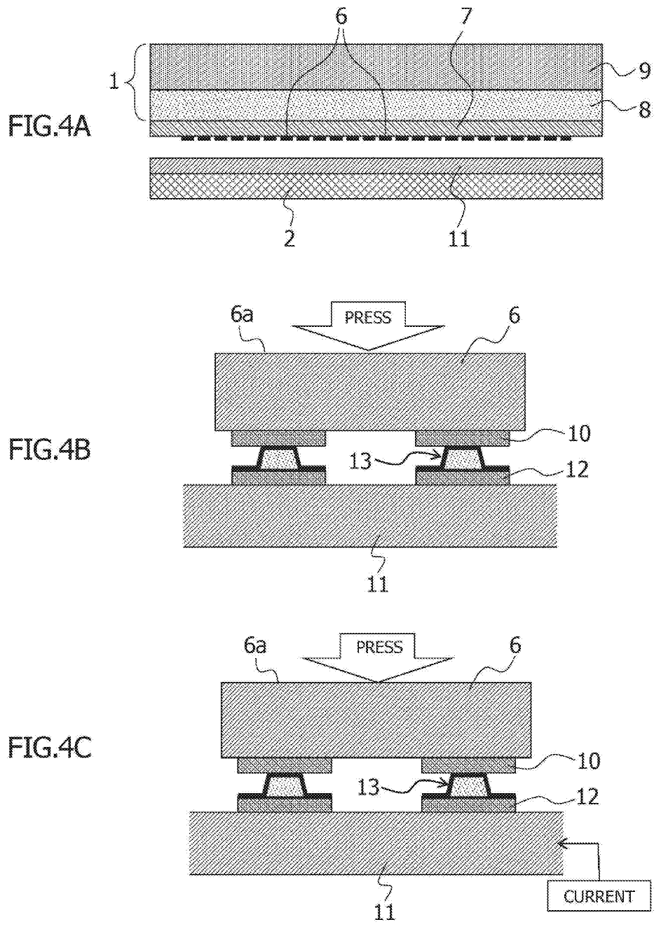

Hereinbelow, the inspection method for LED chips according to the present invention will be described with reference to FIGS. 4A to 4C.

First, referring to FIG. 4A, as a first step, the alignment unit 3 is activated, and the alignment unit 3 horizontally moves and rotates the wafer holding unit 1 in a two-dimensional direction while monitoring alignment marks formed on the sapphire substrate 7 and alignment marks formed on the inspection wiring board 11 by the imaging camera, such that the both alignment marks are aligned at predetermined positional relationships. Each electrode 10 of the multiple micro LED chips 6 is thereby arranged above a corresponding first electrode pad 12 of the inspection wiring board 11.

Next, referring to FIG. 4B, in which the main part is shown enlarged, as a second step, the pressing unit 4 is activated, and the pressing unit 4 moves the wafer holding unit 1 vertically downward, and applies a pressing force to the sapphire substrate 7. At this time, for example, by providing the pressing unit 4 with a pressure sensor, it may be possible to apply a constant, just sufficient, pressing force to the sapphire substrate 7. Thus, the electrodes 10 of the multiple micro LED chips 6 and the multiple first electrode pads 12 of the inspection wiring board 11 are electrically connected. In this case, since a conductive first elastic protrusion 13 is provided on each first electrode pad 12, each electrode 10 of the micro LED chips 6 and a corresponding first electrode pad 12 of the inspection wiring board 11 elastically contact via the first elastic protrusion 13. Thus, it is possible to uniformly electrically connect all electrodes 10 of the micro LED chips 6 formed on the sapphire substrate 7 to the corresponding first electrode pads 12 of the inspection wiring board 11.

Then, referring to FIG. 4C, as a third step, the determination device 5 supplies a current to all the micro LED chips 6 through the inspection wiring board 11, to turn on the micro LED chips 6. An image of the turned-on state of the micro LED chips 6 is obtained by using the image sensor 9 through the sapphire substrate 7 and the transparent member 8 of the wafer holding unit 1. Then, the quality determination is made by the determination device 5 based on the obtained image. For example, when the brightness of a turned-on micro LED chip 6 is equal to or greater than a predetermined reference value and the wavelength of the emitted light is within a predetermined wavelength band, the micro LED chip is determined to be a non-defective product. When the brightness of a turned-on micro LED chip 6 is less than the reference value or the micro LED chip 6 is not turned on, or when the wavelength of the emitted light differs by an amount exceeding an allowable range, the micro LED chip 6 is determined to be a defective product. Then, the position coordinates or address, on the sapphire substrate 7, of micro LED chips 6 determined to be defective are stored. Then, the inspection of the micro LED chips 6 is terminated.

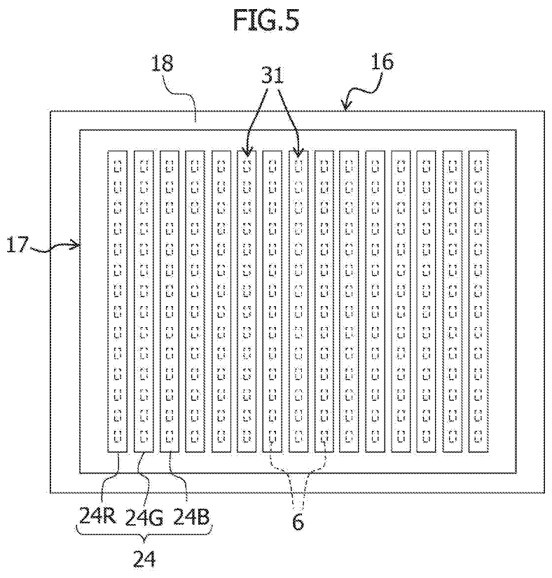

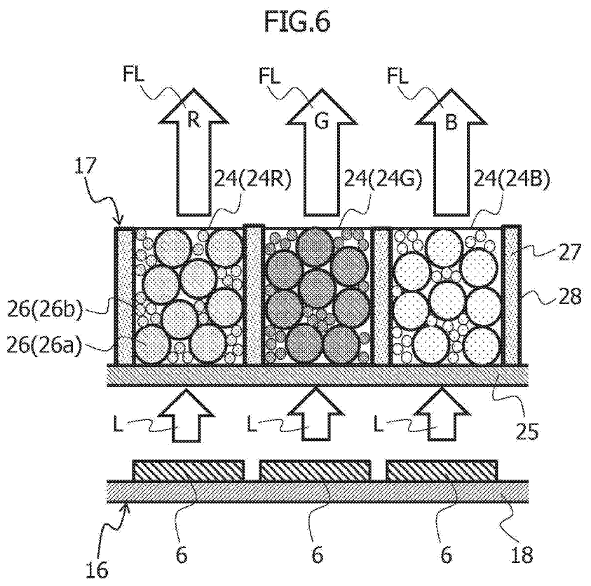

FIG. 5 is a plan view schematically illustrating an LED display according to a first embodiment, manufactured using the inspection method for LED chips, and FIG. 6 is an enlarged cross-sectional view of the main part of FIG. 5. The LED display displays color images, and includes an LED array substrate 16 and a fluorescent layer array 17.

The LED array substrate 16 is provided with multiple micro LED chips 6 arranged in a matrix form, as shown in FIG. 5. The LED array substrate 16 has a structure in which the multiple micro LED chips 6 are arranged on a wiring board for display (“display wiring board”) 18 that includes a flexible board and a TFT drive board including wiring for supplying an image signal to each micro LED chip 6 from a drive circuit provided externally, and that drives the micro LED chips 6 individually to be ON and OFF to turn on and off the micro LED chips 6.

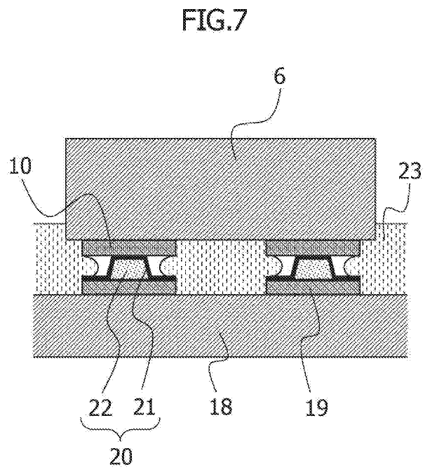

Specifically, the display wiring board 18 is provided with second electrode pads 19, each of which is arranged at the installation position of each micro LED chip 6 so as to be located at a position corresponding to a position of a corresponding electrode 10 of the micro LED chip 6, as shown in FIG. 7. Each second electrode pad 19 is connected to an external drive circuit through wiring (not shown).

The multiple micro LED chips 6 are provided on the display wiring board 18, as shown in FIG. 6. Each micro LED chip 6 emits light in an ultraviolet or blue wavelength band. The micro LEDs 3 are manufactured using gallium nitride (GaN) as a main material. The LED may be an LED that emits a near-ultraviolet light having a wavelength of, for example, 200 nm to 380 nm, or may be an LED that emits a blue light having a wavelength of, for example, 380 nm to 500 nm.

Specifically, as shown in FIG. 7, a micro LED chip 6 is configured such that a electrode 10 of the micro LED chip 6 and a corresponding second electrode pad 19 are electrically connected via a second conductive elastic protrusion 20 formed on the second electrode pad 19 of the display wiring board 18 by patterning.

More specifically, the second elastic protrusion 20 may be a resin columnar protrusion having a surface on which a conductive film of superior conductivity, such as gold or aluminum, is deposited, or may be a columnar protrusion made of a conductive photoresist obtained by adding conductive fine particles, such as silver, to a photoresist, or made of a conductive photoresist containing a conductive polymer. Although FIG. 7 illustrates, as an example, a case in which columnar protrusions 22, each having the surface on which a conductive film 21 is deposited, are formed as the second elastic protrusions 20, the second elastic protrusions 20 may be made of a conductive photoresist.

Furthermore, as shown in FIG. 7, the micro LED chips 6 are bonded and secured to the display wiring board 18 by means of an adhesive layer 23 provided around the second electrode pads 19 of the display wiring board 18. In this case, the adhesive layer 23 is preferably a photosensitive adhesive that is capable of being subjected to patterning by exposure and development. Alternatively, the adhesive layer 10 may be an underfill agent, or an ultraviolet-curable adhesive. In addition, although the photosensitive adhesive may be made of a thermosetting adhesive or an ultraviolet-curable adhesive, a case of the thermosetting adhesive will be described hereinbelow.

The fluorescent layer array 17 is provided above the micro LED chips 6, as shown in FIG. 6. The fluorescent layer array 17 includes multiple fluorescent layers 24, each of which performs wavelength conversion by being excited by excitation light L emitted from corresponding micro LED chips 6 and by emitting fluorescence FL of the corresponding color. The fluorescent layers 24 for red, green and blue colors are separated by partition walls 27 and are provided on a transparent substrate 25. As used herein, “upside” always refers to a side of the display surface regardless of the installation state of the LED display.

Specifically, each fluorescent layer 24 is obtained by mixing and dispersing fluorescent colorants 26a having a larger particle diameter of several tens of microns and fluorescent colorants 26b having a smaller particle diameter of several tens of nanometers in a resist film. Although the fluorescent layer 24 may include only the fluorescent colorants 26a having a larger particle diameter, this may decrease the packing efficiency of the fluorescent colorants, and thus, may increase leakage of excitation light L to the display surface. On the other hand, if the fluorescent layer 24 includes only the fluorescent colorants 26b having a smaller particle diameter, there might have been a problem in that the stability, such as lightfastness, is reduced. Thus, by forming the fluorescent layer 24 to include a mixture of the fluorescent colorants 26a having a larger particle diameter and the fluorescent colorants 26b having a smaller particle diameter, as described above, it is possible to reduce leakage of excitation light L to the display surface and improve the luminous efficiency.

In this case, for the mixing ratio of fluorescent colorants 26 having different particle diameters, it is desired to set the fluorescent colorants 26a having a larger particle diameter to be 50 to 90% by volume, and to set the fluorescent colorants 26b having a smaller particle diameter to be 10 to 50% by volume. Although FIG. 5 shows a case in which the fluorescent layers 24 for red, green, and blue colors are arranged in the form of stripes, a fluorescent layer 24 may be provided above every micro LED chip 6 one by one.

Furthermore, the partition walls 27 provided so as to surround the fluorescent layers 24 for red, green, and blue colors, separate the fluorescent layers 24 for red, green, and blue colors. Each partition wall 27 is made of a transparent resin, such as a transparent photosensitive resin. In order to increase the packing efficiency of the fluorescent colorants 26a having a larger particle diameter in each fluorescent layer 24, it is desired to use a high aspect material having a height-to-width aspect ratio of three or more, as the partition wall 27. As such a high aspect material, SU-8 3000 photoresist, manufactured by Nippon Kayaku Co., Ltd., may be used, for example.

As shown in FIG. 6, a metal film 28 is provided on the surface of each partition wall 27. This metal film 28 is provided to prevent excitation light L and fluorescence FL, which is emitted when the fluorescent layer 24 is excited by the excitation light L, from transmitting through a partition wall 27, and thus, from being mixed with fluorescence FL of the adjacent fluorescent layer 24 of another color. The metal film 28 is formed to have a thickness sufficient to block excitation light L and fluorescence FL. In this case, as the metal film 28, a thin film of aluminum, an aluminum alloy, or the like, that easily reflects excitation light L may be preferable. Thus, excitation light L transmitted through a fluorescent layer 24 to a partition wall 27 is reflected by the metal film 28, such as aluminum, inside the fluorescent layer 24, so as to make the reflected excitation light L used for light emission of the fluorescent layer 24. This results in an improved luminous efficiency of the fluorescent layer 24. Herein, the thin film deposited on the surface of the partition wall 27 is not limited to the metal film 28 that reflects excitation light L and fluorescence FL, and it may be a film that absorbs excitation light L and fluorescence FL.

Next, a manufacturing method for the LED display thus configured will be described.

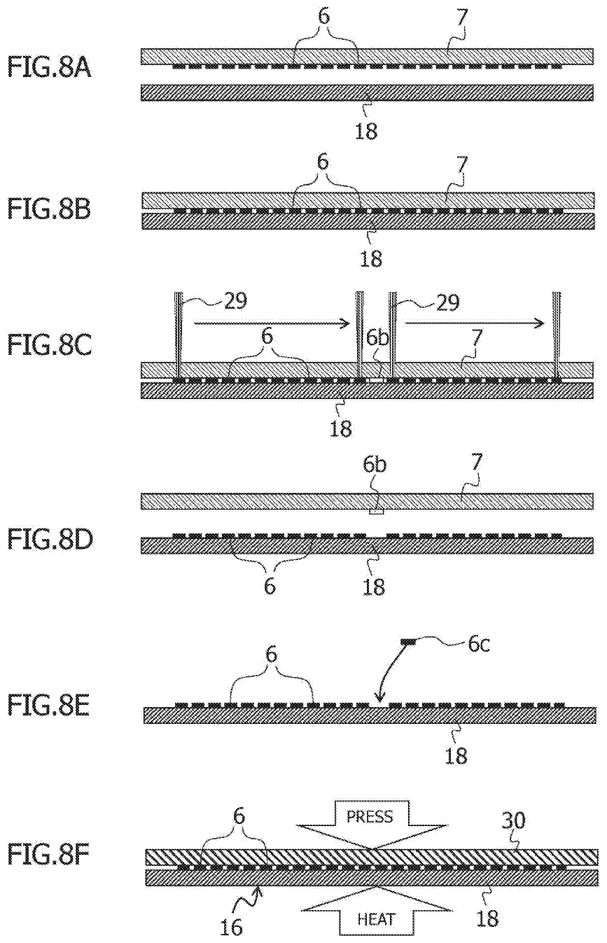

First, a first example of manufacturing the LED array substrate 16 will be described with reference to FIG. 8A to 8F.

After the above-described inspection process (the first to third steps) for micro LED chips 6, the multiple micro LED chips 6 determined as to the quality are subjected to a next process, a manufacturing process for an LED display, without being detached from the sapphire substrate 7.

In a fourth step, which is in the manufacturing process of the LED array substrate 16, the sapphire substrate 7 is positioned above the display wiring board 18 such that each electrode 10 of the multiple micro LED chips 6 formed on the sapphire substrate 7 is arranged above a corresponding second electrode pad 19 provided on the display wiring board 18 at a position corresponding to a position of the electrode 10, as shown in FIG. 8A. Then, the sapphire substrate 7 is placed on the display wiring board 18, as shown in FIG. 8B. Specifically, the sapphire substrate 7 and the display wiring board 18 are relatively moved and rotated while being maintained in parallel to each other, such that alignment marks formed on the sapphire substrate 7 and alignment marks formed on the display wiring board 18 are aligned at predetermined positional relationships by monitoring both alignment marks by the imaging camera (not shown), to perform alignment. Then, the sapphire substrate 7 is placed on the display wiring board 18.

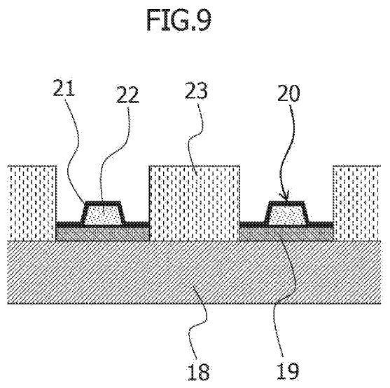

Here, as shown in FIG. 9, a second conductive elastic protrusion 20 is formed in advance on each second electrode pad 19 of the display wiring board 18, and the adhesive layer 23 is formed in advance around the second electrode pads 19.

In this case, a resist for forming a photo spacer is applied to the entire upper surface of the display wiring board 18, and then, the resist is exposed using a photomask and is developed to form a columnar protrusion 22 on each second electrode pad 19 by patterning. Then, on the columnar protrusions 22 and the second electrode pads 19, a conductive film 21 of superior conductivity, such as gold or aluminum, is formed, by sputtering or vapor deposition, for example, to form the second elastic protrusions 20.

Specifically, before forming the conductive film 21, a resist layer is formed by photolithography on the periphery of the second electrode pads 19 (i.e., except on the second electrode pads 19), and after forming the conductive film 21, the resist layer is dissolved with a solution, and thus, the conductive film 21 on the resist layer is lifted off.

The second elastic protrusions 20 may be columnar protrusions, each made of a conductive photoresist obtained by adding conductive fine particles, such as silver, to a photoresist, or a conductive photoresist containing a conductive polymer. In this case, the second elastic protrusions 20 are formed by patterning as the columnar protrusions on the second electrode pads 19, by applying a conductive photoresist to the entire upper surface of the wiring board 18 to a predetermined thickness, exposing the photoresist using a photomask, and developing the photoresist. FIG. 9 shows a case in which the second elastic protrusions 20 are resin columnar protrusions 22, each having the surface on which the conductive film 21 is deposited.

Furthermore, a photosensitive adhesive is applied to the entire upper surface of the display wiring board 18, and then, the adhesive is exposed using a photomask and is developed to remove the photosensitive adhesive applied to the second electrode pads 19, so as to form an adhesive layer 23 by patterning. In this case, the thickness of the applied photosensitive adhesive is set to be greater than a height dimension of the sum of the height of the second electrode pad 19 of the display wiring board 18 and the height of the second elastic protrusion 20, as shown in FIG. 9.

Next, in a fifth step, as shown in FIG. 8C, a micro LED chip 6, which has been determined to be non-defective, is irradiated with a laser beam 29 having a wavelength of, for example, 250 nm to 300 nm, through the sapphire substrate 7, to be selectively lifted off from the sapphire substrate 7, and be mounted on the display wiring board 18.

Specifically, for example, micro LED chips 6 are sequentially irradiated with the laser light 29 from left to right in FIG. 8C. This causes laser ablation so that nitrogen in the GaN layer of the micro LED chips 6 is vaporized, and the micro LED chips 6 are lifted off from the sapphire substrate 7.

For example, when there is included a micro LED chip 6b determined to be defective as illustrated by an open square at the center of FIG. 8C, only non-defective micro LED chips 6, i.e., except for the defective micro LED chip 6b, are subjected to the laser ablation. Thus, when the sapphire substrate 7 is separated from the display wiring board 18, the micro LED chips 6 determined to be non-defective remains on the display wiring board 18, as shown in FIG. 8D. The defective micro LED chip 6b is removed in a state of being attached to the sapphire substrate 7.

Then, as shown in FIG. 8E, a spare micro LED chip 6c, which is non-defective, is supplied to the display wiring board 18 at a missing portion corresponding to the micro LED chip 6b, which has been determined to be defective and has not been lifted off from the sapphire substrate 7. Then, as shown in FIG. 8F, multiple micro LED chips 6 including the spare micro LED chip 6c are collectively pressed with a member 30 having a flat surface, and the adhesive layer 23 is cured by heat. Thus, as shown in FIG. 7, each electrode 10 of the micro LED chips 6 and the corresponding second electrode pad 19 of the display wiring board 18 are electrically connected, and the micro LED chips 6 and the display wiring board 18 are bonded by the adhesive layer 23. The LED array substrate 16 is thus manufactured.

Herein, the laser ablation may be performed by irradiating only micro LED chips 6 determined to be non-defective with a laser beam focused on the interface between the sapphire substrate 7 and the micro LED chips 6, while moving the laser beam in a stepwise manner on the sapphire substrate 7 in the X and Y directions, skipping a micro LED chip 6 determined to be defective.

Alternatively, a laser beam shaped into a linear spot may be moved in a stepwise manner in the row direction while collectively irradiating multiple micro LED chips 6 arranged in a line. Alternatively, the laser light 29 may be divided into multiple beams using a microlens array including multiple microlenses arranged at positions corresponding the positions of the multiple micro LED chips 6, and the divided laser light may be applied to the multiple micro LED chips 6 simultaneously. In these cases, the laser light 29 is not applied to a row or a specific area of micro LED chips 6 including a micro LED chip 6 determined to be defective, and the micro LED chips 6 included in this row or specific area are not lifted off. Thus, after the liftoff, spare micro LED chips 6 are supplied to the display wiring board 18 at the missing portions corresponding to the row or the specific area.

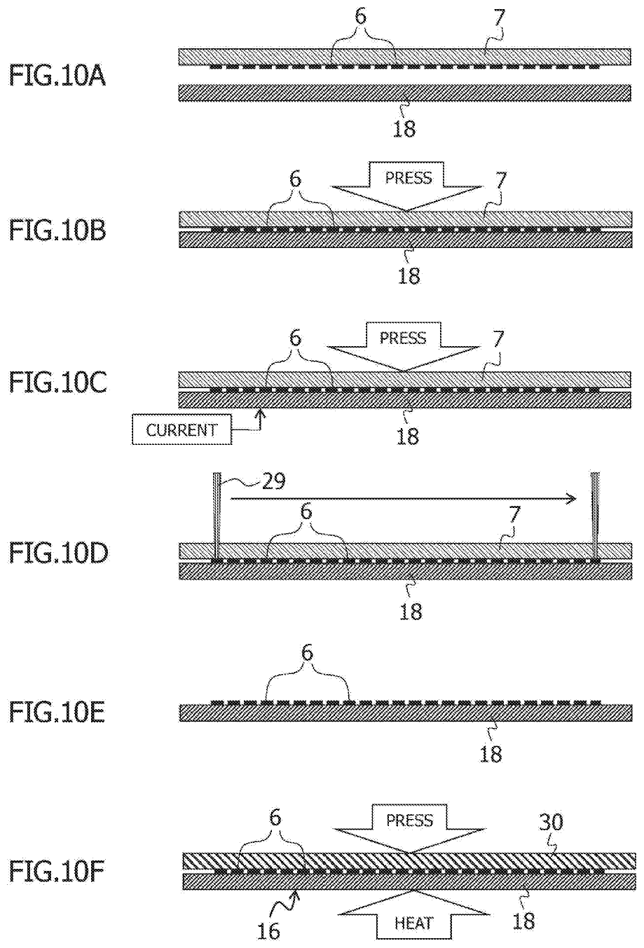

FIGS. 10A to 10F are views illustrating a process in a second example of manufacturing the LED array substrate. According to the second example, the display wiring board 18, which is a component of the LED array substrate 16, is used in the inspection for micro LED chips 6, as shown in FIGS. 4A to 4C, instead of the inspection wiring board 11. Thus, after the inspection of micro LED chips 6, the liftoff of micro LED chips 6 determined to be non-defective is performed directly. Hereinbelow, this will be described in detail with reference to FIGS. 10A to 10F.

First, as shown in FIG. 10A, the sapphire substrate 7 on which multiple micro LED chips 6 are formed, is positioned with respect to the display wiring board 18, and then, as shown in FIG. 10B, the sapphire substrate 7 is pressed downward. Thereby, each electrode 10 of the micro LED chips 6 and a corresponding second electrode pad 19 of the display wiring board 18 are electrically connected via a second elastic protrusion 20, as shown in FIG. 7.

Next, as shown in FIG. 10C, the multiple micro LED chips 6 are supplied with a current through the display wiring board 18, and the quality of the micro LED chips 6 is determined.

Next, as shown in FIG. 10D, micro LED chips 6 determined to be non-defective are irradiated with the laser light 29 through the sapphire substrate 7. Thus, when the sapphire substrate 7 is removed and the micro LED chips 6 determined to be non-defective is lifted off from the sapphire substrate 7, the micro LED chips 6 remain on the display wiring board 18, as shown in FIG. 10E.

Then, as shown in FIG. 10F, all the micro LED chips 6 are collectively pressed with the member 30 having the flat surface, and the adhesive layer 23 is cured by heat. Thus, each electrode 10 of the micro LED chips 6 and the corresponding second electrode pad 19 of the display wiring board 18 are electrically connected, and the micro LED chips 6 and the display wiring board 18 are bonded by the adhesive layer 23, thus completing the LED array substrate 16.

According to the second example of manufacturing the LED array substrate 16, the fourth step in the first example is omitted, and the micro LED chips 6 determined to be non-defective are selectively lifted off immediately after the inspection of micro LED chips 6, resulting in a simplified manufacturing process of the LED array substrate 16.

In the foregoing, all the micro LED chips 6 are collectively pressed and are bonded to the display wiring board 18; however, the present invention is not limited thereto, and the multiple micro LED chips 6 may be pressed and bonded for each unit. For example, the operation “inspection, liftoff, and curing of the adhesive by local heating using a laser” may be repeated every several lines of the micro LED chips 6.

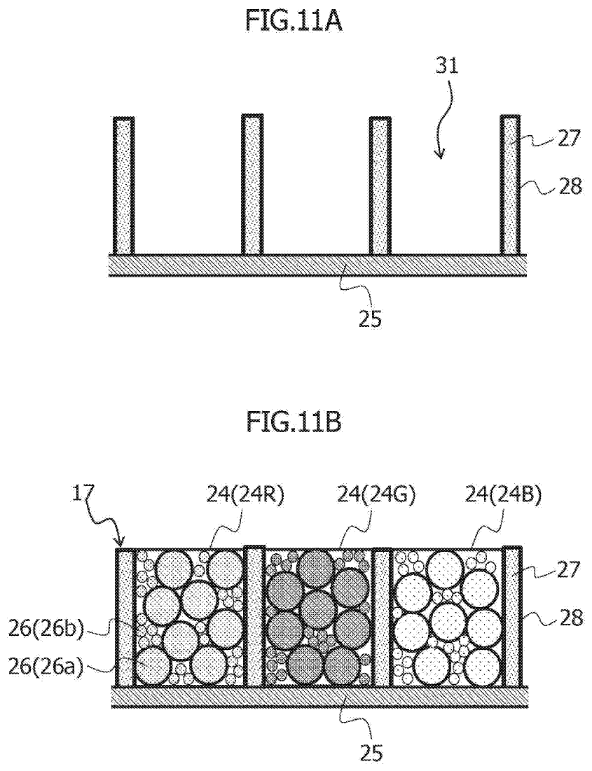

Next, formation of the fluorescent layer array 17 will be described with reference to FIGS. 11A and 11B.

First, referring to FIG. 11A, a transparent photosensitive resin for forming the partition walls 27 is applied to a transparent substrate 25 that transmits therethrough at least light in a near ultraviolet or blue wavelength band and is made of, for example, a glass substrate or a plastic substrate, such as an acrylic resin. Then, the resin is exposed using a photomask and is developed to form the transparent partition walls 27 defining stripes of openings 31, as shown in FIG. 5, for example, at positions where the fluorescent layers 24 are to be formed, each partition wall 27 having a height-to-width aspect ratio of three or more, and having a height of about 20 μm or more. In this case, it may be preferable to use a photosensitive resin of a high aspect material, such as SU-8 3000, manufactured by Nippon Kayaku Co., Ltd., for example.

Next, a metal film 28 of, for example, aluminum or an aluminum alloy, is formed to a predetermined thickness on the partition walls 27 formed on the transparent substrate 25 by applying a known deposition technique, such as sputtering. After the film formation, the metal film 28 deposited on the transparent substrate 25 at the bottom of each opening 31 surrounded by the partition walls 27 is removed by laser irradiation.

Alternatively, a resist or the like may be applied, to a thickness of several μm by inkjet, for example, to the surface of the transparent substrate 25 at the bottom of each opening 31 before the film formation, and then, after forming the metal film 28, the resist and the metal film 28 on the resist may be lifted off and removed. In this case, it will be apparent to one skilled in the art that a chemical solution that does not destroy the resin of the partition walls 27 is selected as a resist solution used for the liftoff.

Next, referring to FIG. 11B, a resist containing, for example, a red fluorescent colorant 26 is applied, by inkjet, for example, to multiple openings 31 for red color, for example, which are surrounded by the partition walls 27. The resist is then cured by ultraviolet irradiation to form red fluorescent layers 24R. Alternatively, the resist containing the red fluorescent colorant 26 may be applied to cover the transparent substrate 25, and then, the resist may be exposed using a photomask and be developed to form red fluorescent layers 24R in multiple openings 31 for red color. In this case, the resist is obtained by mixing and dispersing a fluorescent colorant 26a having a larger particle diameter and a fluorescent colorant 26b having a smaller particle diameter, and the mixing ratio thereof is such that the fluorescent colorant 26a having a larger particle diameter is 50 to 90% by volume and the fluorescent colorant 26b having a smaller particle diameter is 10 to 50% by volume.

Similarly, a resist containing, for example, a green fluorescent colorant 26 is applied, by inkjet, for example, to multiple openings 31 for green color, for example, which are surrounded by the partition walls 27. The resist is then cured by ultraviolet irradiation to form green fluorescent layers 24G. Alternatively, the resist containing the green fluorescent colorant 26, applied to the entire upper surface of the transparent substrate 25 in a similar manner as described above, may be exposed using a photomask and be developed to form green fluorescent layers 24G in multiple openings 31 for green color.

Furthermore, in a similar manner, a resist containing, for example, a blue fluorescent colorant 26 is applied, by inkjet, for example, to multiple openings 31 for blue color, for example, which are surrounded by the partition walls 27. The resist is then cured by ultraviolet irradiation to form blue fluorescent layers 24B. Also, in this case, the resist containing the blue fluorescent colorant 26 applied to the entire upper surface of the transparent substrate 25 may be exposed using a photomask and be developed to form blue fluorescent layers 24B in multiple openings 31 for blue color.

In this case, it may be preferable to provide an antireflection film for preventing external light from being reflected on the display surface of the fluorescent layer array 17. Furthermore, it may be preferable to apply a black paint to the metal film 28 on the display surface side of the partition walls 27. By taking these measures, it is possible to reduce the reflection of external light to the display surface, resulting in improved contrast.

Subsequently, an assembly process of the LED array substrate 16 and the fluorescent layer array 17 is performed.

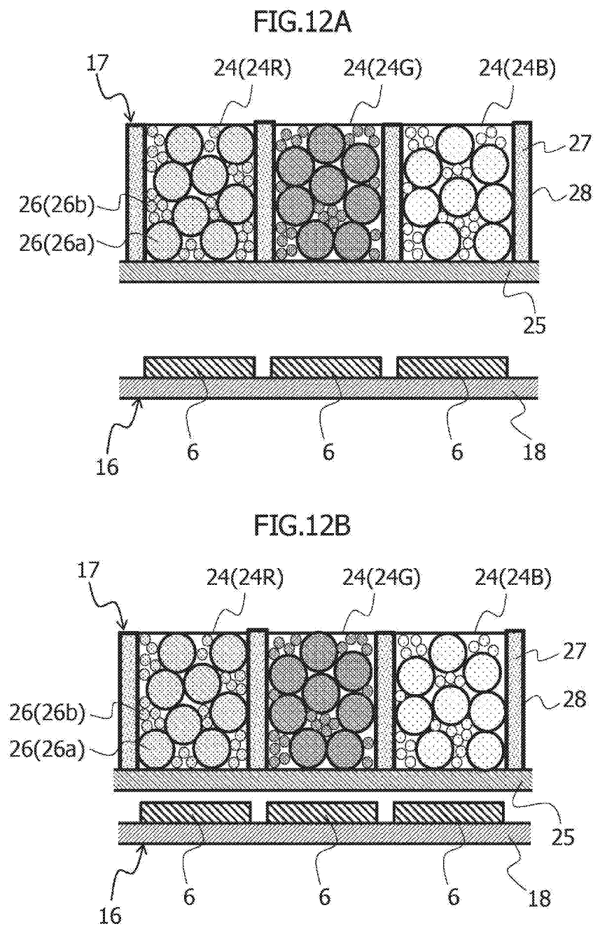

First, as shown in FIG. 12A, the fluorescent layer array 17 is positioned above the LED array substrate 16. Specifically, the fluorescent layers 24 for red, green, and blue colors of the fluorescent layer array 17 are aligned with corresponding LED chips 6 placed on the LED array substrate 16 by using alignment marks formed on the LED array substrate 16 and alignment marks formed on the fluorescent layer array 17.

When the alignment of the LED array substrate 16 and the fluorescent layer array 17 is completed, the LED array substrate 16 and the fluorescent layer array 17 are joined by an adhesive (not shown), as shown in FIG. 12B, thus completing an LED display.

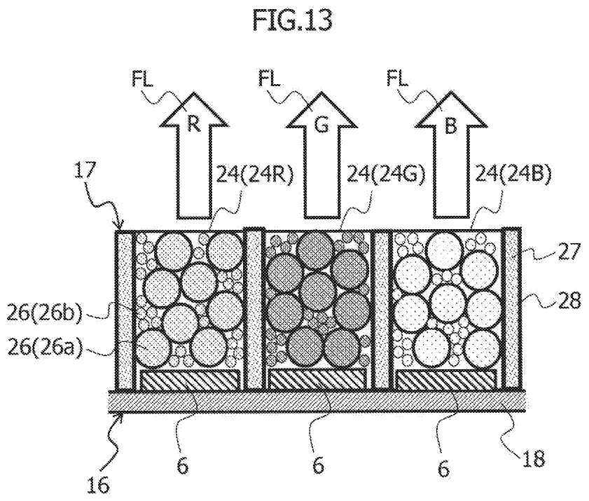

FIG. 13 is an enlarged cross-sectional view of the main part of an LED display according to a second embodiment. Although, the LED display is described including the LED array substrate 16 and the fluorescent layer array 17 in the first embodiment, the fluorescent layers 24 for red, green, and blue colors, and the partition walls 27 are placed directly on the LED array substrate 16 in the second embodiment, as shown in FIG. 13. The LED display thus configured can be manufactured by performing the above-described forming process of the fluorescent layer array 17, on the LED array substrate 16.

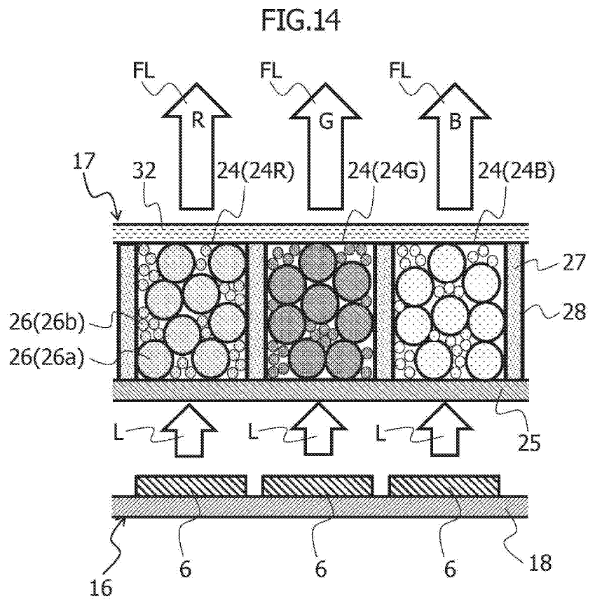

FIG. 14 is an enlarged cross-sectional view of the main part of an LED display according to a third embodiment. In the third embodiment, there is provided an excitation light blocking layer 32 that covers the fluorescent layers 24 for red, green and blue colors, and the partition walls 27, to block excitation light L. This excitation light blocking layer 32 selectively reflects or absorbs light in the same wavelength band as the excitation light L, contained in external light, such as sunlight, to prevent the fluorescent layers 24 from being excited by such light and from emitting light, so as to improve color reproduction.

Specifically, when the excitation light L is ultraviolet light, the excitation light blocking layer 32 is provided so as to cover the fluorescent layers 24 for red, green and blue colors, and the partition walls 27, as shown in FIG. 14. In a case in which the excitation light L is light in the blue wavelength band, it may be preferable to provide the excitation light blocking layer 32 so as to cover fluorescent layers 24 except for the blue fluorescent layers 24B, and the partition walls 27.

Although FIG. 14 shows a case in which the excitation light blocking layer 32 is applied to the LED display according to the first embodiment, as shown in FIG. 6, as an example, the excitation light blocking layer 32 may also be applied to the LED display according to the second embodiment, as shown in FIG. 13.

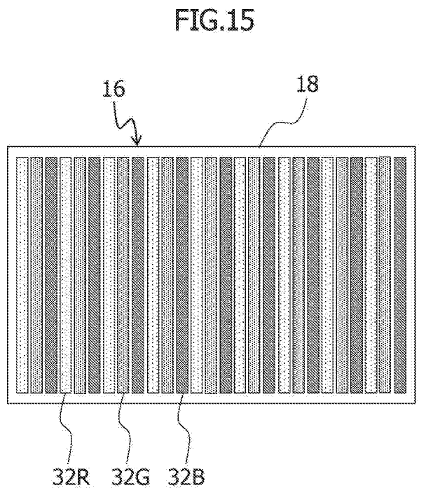

FIG. 15 is a plan view schematically illustrating an LED display according to a fourth embodiment. The fourth embodiment is different from the first to third embodiments in that there is provided an LED array substrate 16 on which red, green, and blue micro LED chips 6 are arranged, and the fluorescent layer array 17 is omitted. In order to simplify the drawing, FIG. 15 shows the red, green, and blue LED chip rows 32R, 32G, and 32B, instead of the micro LED chips 6. Hereinbelow, a manufacturing method for the LED display according to the fourth embodiment will be described with reference to the drawings.

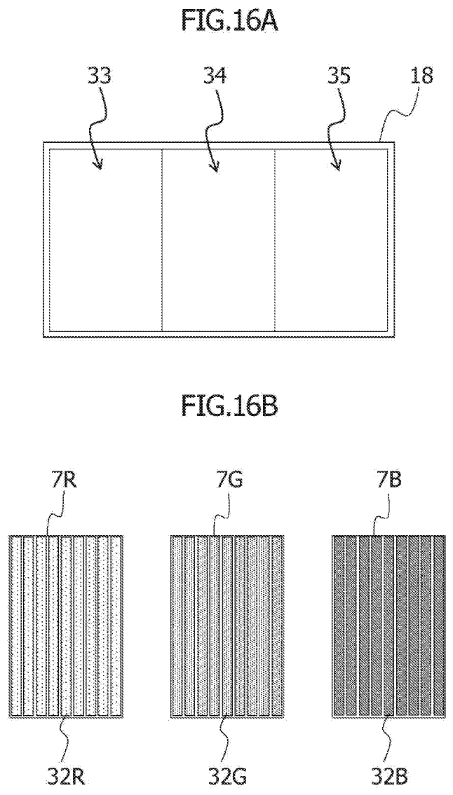

First, as shown in FIG. 16A, the display area of the display wiring board 18 is divided into integer multiples of three. Here, a case in which the display area is divided into three areas 33, 34, and 35, will be described.

For the divided areas 33, 34 and 35, there are prepared a sapphire substrate 7R for red color, on which multiple red LED chip rows 32R are formed, a sapphire substrate 7G for green color, on which multiple green LED chip rows 32G are formed, and a sapphire substrate 7B for blue color, on which multiple blue LED chip rows 32B are formed, as shown in FIG. 16B. These sapphire substrates 7 have been subjected to quality inspection for micro LED chips 6 by the inspection method for LED chips according to the present invention. Here, a case in which all the micro LED chips 6 are determined to be non-defective, will be described.

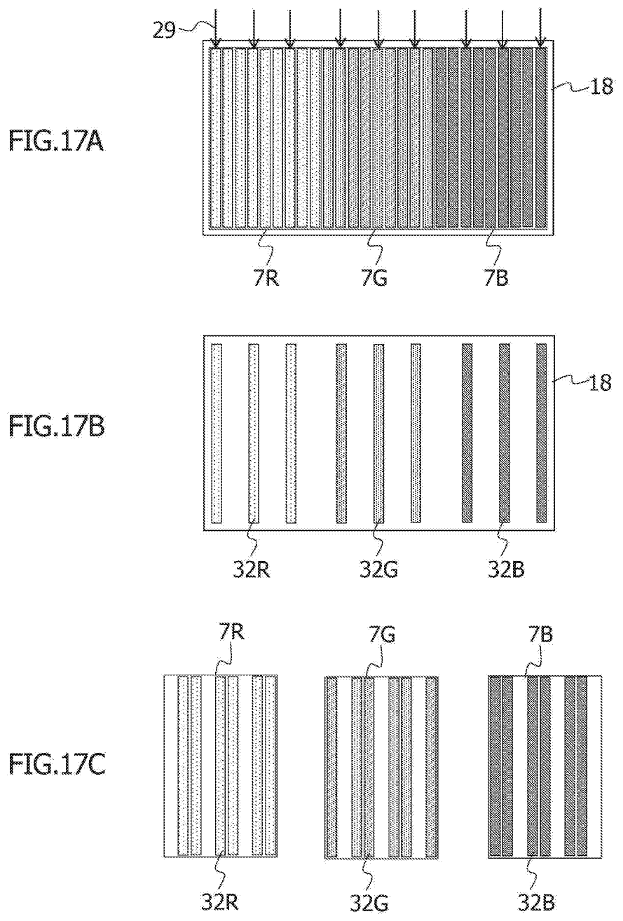

FIGS. 17A to 17C are explanatory views illustrating a first liftoff.

First, referring to FIG. 17A, the sapphire substrate 7R for red color is positioned and placed on the area 33 of the display wiring board 18 in FIG. 16A. Then, as indicated by arrows in FIG. 17A, each red LED chip row 32R corresponding to each red LED arrangement area is irradiated with a laser light 29. Micro LED chips 6 in the red LED chip rows 32R are thus lifted off from the sapphire substrate 7R and remain on the display wiring board 18, as shown in FIG. 17B.

Similarly, as shown in FIG. 17A, the sapphire substrate 7G for green color is placed on the region 34 of the display wiring board 18 in FIG. 16A, and the sapphire substrate 7B for blue color is placed on the region 35. Then, as indicated by arrows, each green LED chip row 32G corresponding to each green LED arrangement area and each blue LED chip row 32B corresponding to each blue LED arrangement area are irradiated with laser lights 29. Micro LED chips 6 in the green and blue LED chip rows 32G, 32B are thus lifted off from the sapphire substrates 7G, 7B, and remain on the display wiring board 18, as shown in FIG. 17B.

FIG. 17C is a plan view showing the red, green and blue LED chip rows 32R, 32G and 32B, remaining on the sapphire substrates 7R, 7G and 7B for red, green and blue colors after the first liftoff. These sapphire substrates 7 are then used in a second liftoff.

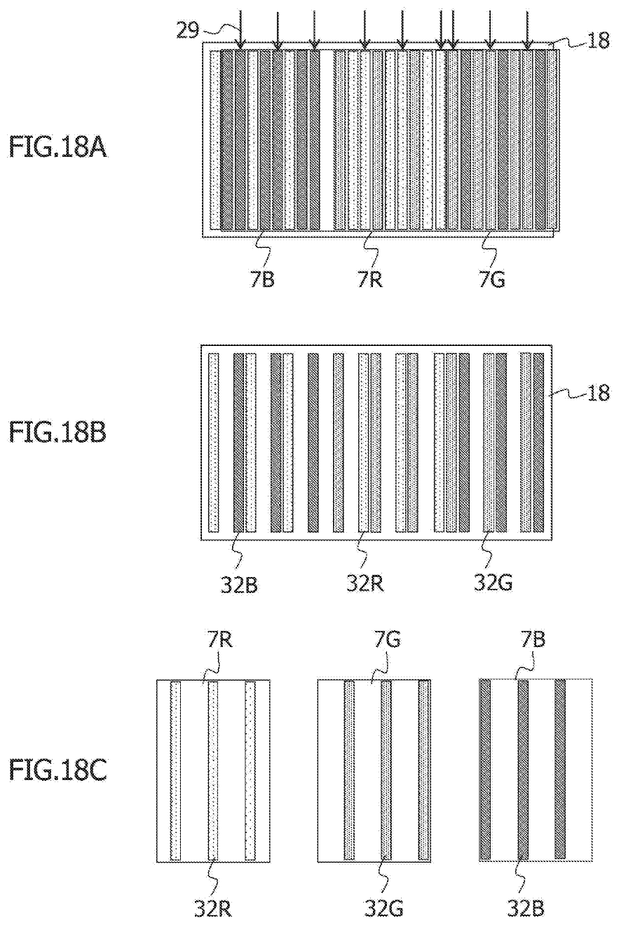

FIGS. 18A to 18C are explanatory views illustrating a second liftoff.

Referring to FIG. 18A, the sapphire substrate 7B for blue color is positioned and placed on the region 33 of the display wiring board 18 in FIG. 16A. The sapphire substrate 7R for red color is positioned and placed on the region 34. The sapphire substrate 7G for green color is positioned and placed on the region 35.

Then, as indicated by arrows in FIG. 18A, blue, red and green LED chip rows 32B, 32R and 32G, corresponding to the blue, red, and green LED arrangement areas, respectively, are irradiated with laser light 29. Micro LED chips 6 in the blue, red and green LED chip rows 32B, 32R and 32G are thus lifted off from the sapphire substrates 7B, 7R and 7G, and remain on the display wiring board 18, as shown in FIG. 18B.

FIG. 18C is a plan view showing the red, green, and blue LED chip rows 32R, 32G and 32B, remaining on the sapphire substrates 7R, 7G and 7B for red, green and blue colors after the second liftoff. These sapphire substrates 7 are then used in a third liftoff.

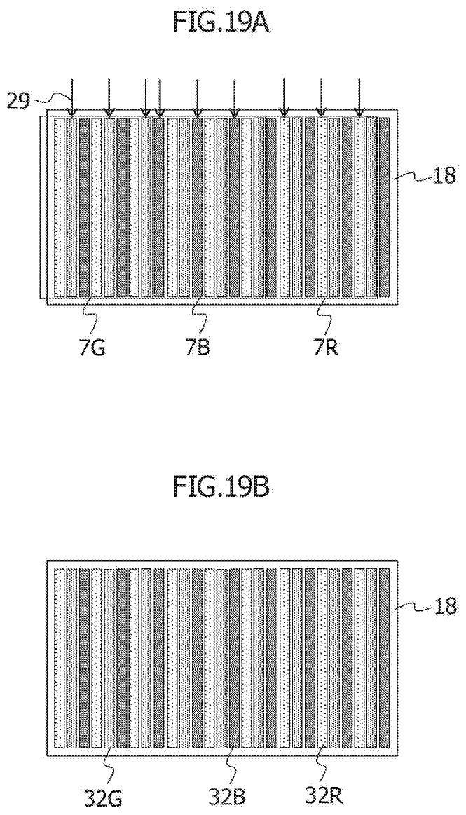

FIGS. 19A and 19B are explanatory views illustrating a third liftoff.

Referring to FIG. 19A, the sapphire substrate 7G for green color is positioned and placed on the region 33 of the display wiring board 18 in FIG. 16A. The sapphire substrate 7B for blue color is positioned and placed on the region 34. The sapphire substrate 7R for red color is positioned and placed on the region 35.

Then, as indicated by arrows in FIG. 19A, green, blue and red LED chip rows 32G, 32B and 32R, corresponding to the green, blue, and red LED arrangement areas, respectively, are irradiated with laser light 29. Micro LED chips 6 in the green, blue and red LED chip rows 32G, 32B and 32R are thus lifted off from the sapphire substrates 7G, 7B and 7R, and remain on the wiring board 18, as shown in FIG. 19B. In this way, the micro LED chips 6 for red, green and blue colors can be arranged on the display wiring board 18 without omissions. Then, multiple micro LED chips 6 are collectively pressed with the member 30 having the flat surface, and the adhesive layer 23 is cured by heat, as shown in FIG. 8F, thus completing the LED display.

According to the manufacturing method for an LED display of the present invention, it is possible to perform quality inspection without detaching the micro LED chips 6 from the sapphire substrate 7. Furthermore, after the inspection, since only non-defective micro LED chips 6 are lifted off, it is possible to proceed the process without wastefully handling a defective micro LED chip 6, resulting in improved manufacturing efficiency of an LED display.

It should be noted that the entire contents of Japanese Patent Application No. 2017-207183, filed on Oct. 26, 2017, on which convention priority is claimed, is incorporated herein by reference.

It should also be understood that many modifications and variations of the described embodiments of the invention will be apparent to one of ordinary skill in the art, without departing from the spirit and scope of the present invention as claimed in the appended claims.

What is claimed is:

1. An inspection method for multiple light emitting diode (LED) chips formed on a wafer, comprising:
a first step of positioning the wafer above a wiring board such that each electrode of the multiple LED chips formed on the wafer is arranged above a corresponding electrode pad of provided on the wiring board, and then placing the wafer on the wiring board;
a second step of electrically connecting each electrode of the multiple LED chips and the corresponding electrode pad of the wiring board; and
a third step of supplying a current to the multiple LED chips through the wiring board, and determining quality of the LED chips.

2. The inspection method for LED chips, according to claim 1, wherein each electrode of the LED chips and the corresponding electrode pad of the wiring board are electrically connected via a conductive elastic protrusion formed on the electrode pad.

3. The inspection method for LED chips, according to claim 1, wherein the LED chips are micro LED chips formed on a transparent wafer.

4. An inspection device for an LED chip for use in the inspection method for LED chips according to claim 1, comprising:
a wafer holding unit that holds a wafer on which multiple LED chips are formed;
a wiring board holding unit arranged to face the wafer holding unit, wherein the wiring board holding unit holds a wiring board provided with multiple electrode pads at positions corresponding to positions of electrodes of the multiple LED chips;
an alignment unit that positions the wafer with respect to the wiring board such that each electrode of the multiple LED chips formed on the wafer is arranged above a corresponding electrode pad provided on the wiring board;
pressing unit that presses at least one of the wafer and the wiring board, to electrically connect each electrode of the multiple LED chips and the corresponding electrode pad of the wiring board; and
a determination device that supplies a current to the multiple LED chips through the wiring board, and determines quality of the LED chips.

5. A manufacturing method for an LED display, for use in mounting multiple micro LED chips formed on a transparent wafer on a wiring board after subjecting the multiple micro LED chips to the inspection method according to claim 1, comprising:
a first step of positioning the wafer above an inspection wiring board such that each electrode of the multiple micro LED chips formed on the wafer is arranged above a corresponding first electrode pad provided on the inspection wiring board, and then placing the wafer on the inspection wiring board;
a second step of pressing the wafer to electrically connect each electrode of the multiple micro LED chips and the corresponding first electrode pad of the inspection wiring board;
a third step of supplying a current to the multiple micro LED chips through the inspection wiring board, and determining quality of the micro LED chips;
a fourth step of positioning the wafer above a display wiring board such that each electrode of the multiple micro LED chips formed on the wafer is arranged above a corresponding second electrode pad provided on the display wiring board, and then placing the wafer on the display wiring board; and
a fifth step of irradiating micro LED chips determined to be non-defective with a laser light through the wafer, to selectively lift off, from the wafer, the irradiated micro LED chips, and to mount the lifted-off micro LED chips on the display wiring board.

6. The manufacturing method for an LED display, according to claim 5, wherein the second step comprises electrically connecting each electrode of the micro LED chips and the corresponding first electrode pad of the inspection wiring board via a first conductive elastic protrusion formed on the first electrode pad.

7. The manufacturing method for an LED display, according to claim 5, wherein the fifth step comprises: supplying a spare micro LED chip to the display wiring board at a missing portion corresponding to a micro LED chip, which has been determined to be defective and has not been lifted off from the wafer; and then curing an adhesive layer provided around second electrode pads of the display wiring board, while pressing the micro LED chips including the spare micro LED chip to electrically connect each electrode of the micro LED chips and the corresponding second electrode pad of the display wiring board, to secure the micro LED chips to the display wiring board.

8. The manufacturing method for an LED display, according to claim 7, wherein each electrode of the micro LED chips and the corresponding second electrode pad of the display wiring board are electrically connected via a second conductive elastic protrusion formed on the second electrode pad.

9. The manufacturing method for an LED display, according to claim 7, wherein the adhesive layer is made of a photosensitive adhesive adapted to be subjected to a patterning by exposure and development, and the adhesive layer is provided on the display wiring board in advance.

10. The manufacturing method for an LED display, according to claim 5, wherein the display wiring board is used in place of the inspection wiring board, wherein the fourth step is omitted, and the fifth step is performed following the third step.
